(19) United States
(12) Patent Application Publication
(10) Pub. No.: US 2011/0040505 A1
(43) Pub. Date: Feb. 17, 2011

(54) Testing System and Method for Testing Charging Circuit

(76) Inventors: Te-Lung Wu, Taipei Hsien (TW); Chun-Ta Lee, Taipei Hsien (TW); Tzu-Heng Yeh, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 12/767,806

(22) Filed: Apr. 27, 2010

(30) Foreign Application Priority Data
Aug. 17, 2009 (TW) 098127569

(51) Int. Cl. G01R 31/36

(52) U.S. Cl. 702/63

(57) ABSTRACT

A testing system for testing a charging circuit includes a setting unit, a virtual battery, and a control device. The setting unit is utilized for setting a charging configuration of the charging circuit according to a battery status message, to make the charging circuit to output a charging power accordingly. The virtual battery includes a battery status generating unit for generating the battery status message according to a first control signal, and a load unit for generating a load for the charging circuit according to a second control signal, so as to receive the charging power outputted from the charging circuit, and recording variation of the charging power. The control device is utilized for generating the first control signal and the second control signal, and storing information recorded by the load unit as a digital data for evaluate the charging circuit.

### BACKGROUND OF THE INVENTION

1. Field of the Invention

The present invention relates to a testing system and method for testing a charging circuit, and more particularly, to a testing system and method capable of enhancing testing efficiency and flexibility, and free from limitation of manufacturing procedures of other elements.

2. Description of the Prior Art

With technology development and industry progress, portable electronic devices, such as laptops, cell-phones, cameras, and mp3 players, are widely used in daily life. In order to enhance portability, a portable electronic device is equipped with a rechargeable battery for storing operating power.

The rechargeable battery is an energy storage device capable of performing charging and discharging repetitively. When there is no external power supply, the rechargeable battery releases stored electricity in order to drive the portable electronic device to execute normal operations. On the contrary, while receiving an external power supply, the portable electronic device is driven by the external power supply, and charges the rechargeable battery via a charging circuit. Therefore, in addition to the rechargeable battery, maintenance of normal operation of the charging circuit is also a dominant factor to ensure normal operations of the rechargeable battery.

In general, to ensure normal operations of the charging circuit of the portable electronic device, the charging circuit undergoes various tests before marketing. A testing method is to charge a rechargeable battery via the charging circuit, and check whether the charging circuit works normally according to related data of the charging process. Please refer to FIG. 1. FIG. 1 is a schematic diagram of a testing system 10 in the prior art. The testing system 10 is used for testing an operating status of a charging circuit 100 of a portable electronic device. When an external power supply PWR plugs in, a charger firmware 102 reads information such as capacity and configuration of a rechargeable battery 104 through routes R1_1 and R1_2, and passes the information to the charging circuit 100 through the route R1_1 in order to initialize the charging circuit 100. Then, according to the information read from the charger firmware 102, the charging circuit 100 outputs power to the rechargeable battery 104 through a route R_2, so as to perform charging. A sense resistor 106 is included in the route R2, and used to sense charging voltage and current outputted from the charging circuit 100. The sense results of the sense resister 106 are recorded by a recorder 108. Furthermore, data recorded by the recorder 108 can be transformed into an adequate charging curve, whereby a testing staff can judge if the charging circuit 100 performs normal operations. For example, if the charging circuit 100 is predefined to use a constant current charging mode first and then a constant voltage charging mode, to charge the rechargeable battery 104. Therefore, according to data recorded by the recorder 108, the testing staff is able to judge if the charging circuit 100 follows the predefined charging process, so as to evaluate the operation of the charging circuit 100.

In order to test the complete operating status of the charging circuit 100, electricity stored in the rechargeable battery 104 is set to empty or nearly empty. In other words, required testing time is at least the time for charging the rechargeable battery 104 from empty to full power, upward two hours in general. Under the circumstances, if any error occurs in the charger firmware 102 or the rechargeable battery 104 during testing, the first step is to find out the malfunctioned device, and then restart the two-hour testing. Obviously, such testing method is extremely time-wasting and hence downgrades manufacturing efficiency.

In addition, before testing the charging circuit 100, designing and manufacturing of the charger firmware 102 and the rechargeable battery 104 must be accomplished. That is to say, even if research and design staffs have finished the charging circuit 100, the charger circuit 100 cannot be tested on condition that the charger firmware 102 and the rechargeable battery 104 do not exist, which results in delay of marketing, as well as downgrades product competitiveness.

Therefore, improving the prior art testing method for testing charging circuits is necessary.

### SUMMARY OF THE INVENTION

It is therefore a primary objective of the claimed invention to provide a testing system and method for testing a charging circuit.

The present invention discloses a testing system for testing a charging circuit, which comprises a setting unit, a virtual battery, and a control device. The setting unit is utilized for setting a charging configuration of the charging circuit according to a battery status message, to control the charging circuit to output a charging power accordingly. The virtual battery includes a battery status generating unit for generating the battery status message according to a first control signal, and a load unit for generating a load for the charging circuit according to a second control signal, so as to receive the charging power outputted from the charging circuit, and recording variation of the charging power. The control device is utilized for generating the first control signal and the second control signal, and storing information recorded by the load unit as a digital data for evaluate the charging circuit.

The present invention further discloses a testing method for testing a charging circuit, which comprises generating a battery status message when the charging circuit receives an external power supply, setting a charging configuration of the charging circuit according to the battery status message, to control the charging circuit to output a charging power, and generating a load for the charging circuit, for receiving the charging power outputted from the charging circuit, and recording variation of the charging power, for evaluating the charging circuit.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a testing system in the prior art.

FIG. 2. is a schematic diagram of a testing system according to an embodiment of the present invention.

FIG. 3 is a schematic diagram of a testing system according to another embodiment of the present invention.

FIG. 4 is a flowchart of a testing process according to an embodiment of the present invention.

### DETAILED DESCRIPTION

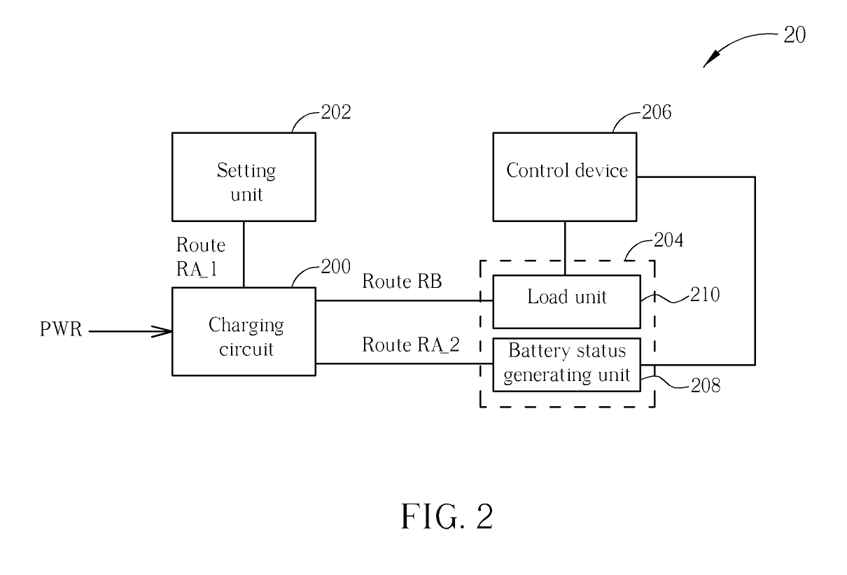

Please refer to FIG. 2. FIG. 2. is a schematic diagram of a testing system 20 according to an embodiment of the present invention. The testing system 20 is utilized for testing a charging circuit 200, and comprises a setting unit 202, a virtual battery 204, and a control device 206. In the testing system 20, the virtual battery 204 is used for simulating a rechargeable battery, and comprises a battery status generating unit 208 and a load unit 210, both controlled by a control device 206. The battery status generating unit 208 generates a battery status message for simulating battery status according to settings provided by the control device 206, while the load unit 210 generates a corresponding load according to settings of the control device 206, in order to receive charging power outputted from the charging circuit 200, and record variation of the charging power. In detail, when the charging circuit 200 receives an external power supply PWR, the setting unit 202 reads the battery status message generated by the battery status generating unit 208 through routes RA_1 and RA_2, and sets a charging configuration of the charging circuit 200 through the route RA_1 accordingly. Based on the charging configuration set by the setting unit 202, the charging circuit 200 outputs the charging power to the load unit 210 through a route RB, in order to record the variation of the charging power. And, the control device 206 stores the variation of the charging power, recorded by the load unit 210, as digital data for evaluating the charging circuit 200.

In short, the present invention utilizes the virtual battery 204 to simulate a rechargeable battery. Therefore, by adequately setting load variation of the load unit 210, the behavior of a rechargeable battery being charged from empty to full power can be completely simulated in shorter time, which is used for determining whether the charging circuit 200 works normally. That is to say, while performing testing on the charging circuit 200 via the testing system 20, a testing staff has to plug in the external power supply PWR to the charging circuit 200 first. Then, the setting unit 202 reads the battery status message generated by the battery status generating unit 208, such as information of capacity and configuration, through the routes RA_1 and RA_2, in order to determine the status of the virtual battery 204, and passes the settings, such as charging configuration and charging procedure, to the charging circuit 200 accordingly, so as to initialize the charging circuit 200. Next, the charging circuit 200 outputs the charging power to the load unit 210 through the route RB according to the charging configuration set by the setting unit 202. Since the load variation of the load unit 210 is related to that of a rechargeable battery being charged from empty to full power, a power output process of the charging circuit 200 also reflects the behavior of the rechargeable battery being charged from empty to full power. As a result, based on variation of power received by the load unit 200, the testing staff is able to judge when the charging circuit 200 follows predefined charging steps, so as to evaluate the operation of the charging circuit 200.

As can be seen from the above, in the testing system 20, the virtual battery 204 simulates the rechargeable battery according to the control signal of the control device 206. In other words, from viewpoint of the charging circuit 200 and the setting unit 202, the virtual battery 204 can be seen as a physical rechargeable battery. Hence, in practice, the testing staff can manipulate the control device 206 to set the battery status message, generated by the battery status generating unit 208, and the load variation of the load unit 210 according to specification of a required rechargeable battery. Under the circumstances, the testing staff does not need to replace the virtual battery 204, but utilizes the virtual battery 204 via the control device 206 to simulate different rechargeable batteries or the same battery with different capacities. More importantly, the load variation of the load unit 210 is also controlled by the control device 206, such that the testing staff is able to control the load unit 210 via the control device 206, to present a specific load variation, such as the load variation of the rechargeable battery from empty to full power or from half to three-fourth power, in a short time, and further detect and observe whether the power output process of the charging circuit 200 conforms to the predefined charging steps.

In the prior art, to test complete operating status of a charging circuit, the charging circuit has to charge a physical rechargeable battery from empty to full power, and then the testing staff can determine whether the charging circuit is under normal operation according to variation of charging voltage and current during the charging process. Therefore, the prior art takes a quite long testing time. Meanwhile, if any error occurs in other devices, the long-winded charging process must be re-performed. Hence, the prior art is time-wasting and without flexibility. In comparison, in the present invention, the virtual battery 204 simulates the load variation of an on-charging rechargeable battery in a short time, and therefore enormously decreases the testing time. Meanwhile, the present invention can adjust the battery status generating unit 208 or the load unit 210 based on different needs, for determining whether the charging circuit 200 performs accurate operation with different rechargeable batteries equipped or different power provided. As a result, the present invention not only upgrades the testing efficiency substantially, but also enhances flexibility.

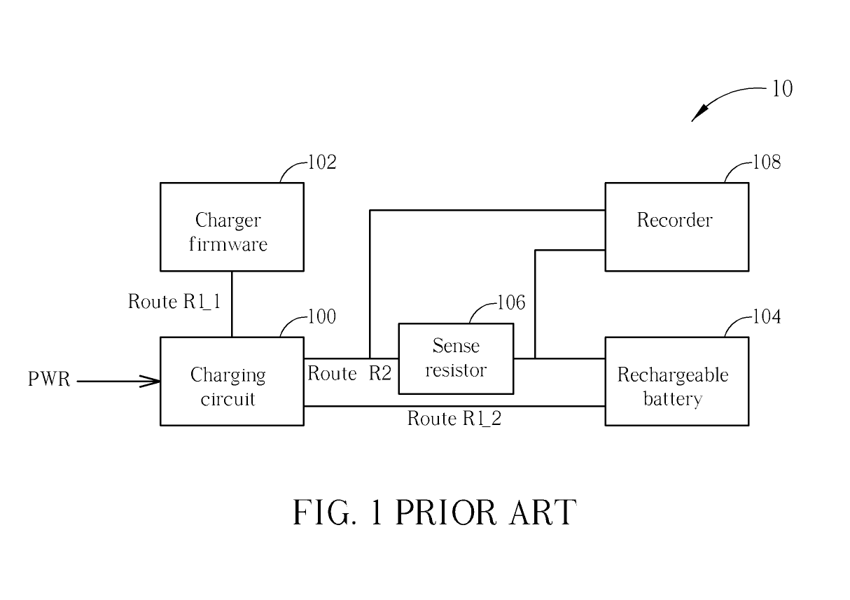

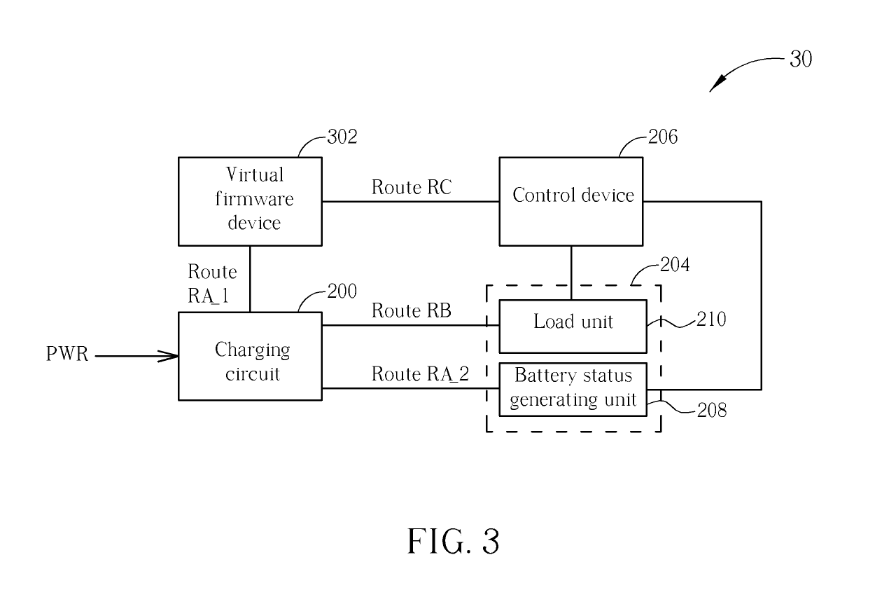

Please note that, the testing system 20 depicted in FIG. 2 is merely an embodiment of the present invention. Those skilled in the art can make alternations and modifications accordingly, and is not limited herein. For example, the charging circuit 200 is preferably included in a portable electronic device, such as a laptop, cell-phone, or PDA. In addition, in FIG. 2, the setting unit 202 is utilized to set the charging configuration of the charging circuit 200, and can refer to a firmware device embedded in a portable device, like the charging firmware 102 in FIG. 1. Practically, the setting unit 202 can also be replaced by an external virtual firmware device. Please refer to FIG. 3. FIG. 3 is a schematic diagram of a testing system 30 according to an embodiment of the present invention. The testing system 30 is similar to the testing system 20 illustrated in FIG. 2, but replaces the setting unit 202 with a virtual firmware device 302. The virtual firmware 302 is controlled by the control device 206 through a route RC, and utilized for setting the charging configuration of the charging circuit 200 according to commands of the control device 206. In other words, even if research and design staffs have not yet finished the firmware of the charging circuit 200, the present invention can still control the virtual firmware device 302 via the control device 206 to set the charging configuration of the charging circuit 200. Therefore, the testing of the charging circuit 200 is not restricted by the manufacturing procedure of the firmware or charging circuit, so as to decrease time to market and enhance product competitiveness.

On the other hand, in the present invention, the control device 206 is utilized for controlling the virtual battery 204 or the virtual firmware device 302, and recording variation of voltage and current received by the load unit 210, which can be preferably realized by a computer system. In addition, in FIG. 2 and FIG. 3, the connections between elements are denoted by continuous lines. Nevertheless, these lines are not limited to the single-wire type in practice, and can vary with different applications accordingly. For example, if the control device 206 and the battery status generating unit 208 communicate with each other via USB interface, there are four wires according to the USB specification. Furthermore, methods to connect the elements are not limited to any specific configuration, and can be adequately selected from interface specifications, such as USB, SM-Bus, etc., based on the system requirements.

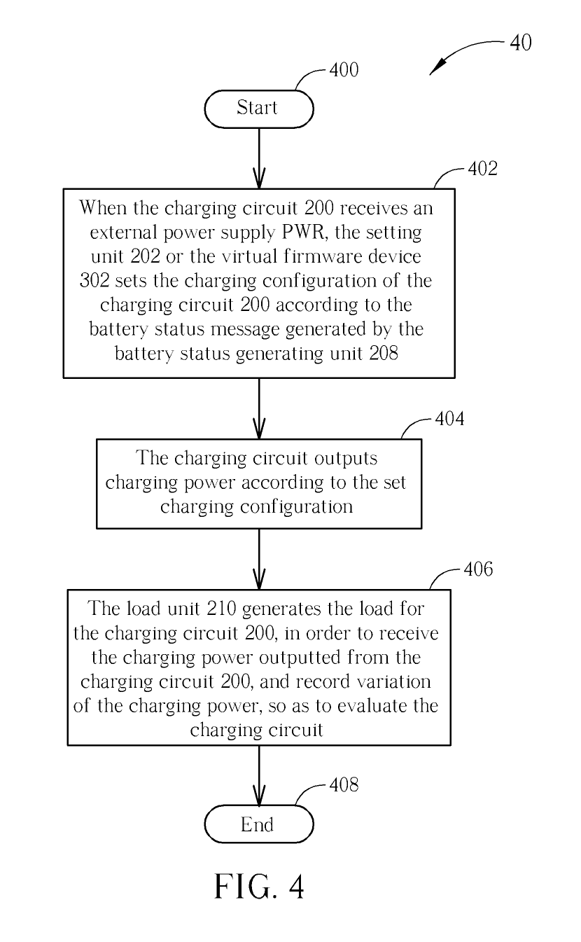

Operations of the testing system 20 or the testing system 30 can be further summarized into a testing process 40, as shown in FIG. 4. The testing process 40 comprises the following steps:

Step 400: Start.

Step 402: When the charging circuit 200 receives an external power supply PWR, the setting unit 202 or the virtual firmware device 302 sets the charging configuration of the charging circuit 200 according to the battery status message generated by the battery status generating unit 208.

Step 404: The charging circuit outputs charging power according to the set charging configuration.

Step 406: The load unit 210 generates the load for the charging circuit 200, in order to receive the charging power outputted from the charging circuit 200, and record variation of the charging power, so as to evaluate the charging circuit

Step 408: End.

Detailed description of the process 40 is stated above and is not narrated herein.

In conclusion, the present invention utilizes the virtual battery to, in a short time, simulate the load variation of a rechargeable battery being charged, and as shown from experimental results, the testing time can be curtailed from two hours of the prior art to three minutes. Besides the reduction of testing time, the present invention adjusts the virtual battery based on different requirements for determining the operative behavior of the charging circuit with different batteries or power, so as to enhance testing flexibility. In addition, in the present invention, the testing of the charging circuit is not limited to the manufacturing procedure of the firmware or the rechargeable battery, such that manufacturing time can be reduced, and product competitiveness can be upgraded. Therefore, the present invention substantially enhances testing efficiency and flexibility, and is not limited to the manufacturing procedure of other elements, to decrease manufacturing time, and raise product competitiveness.

Those skilled in the art will readily observe that numerous modifications and alterations of the device and method may be made while retaining the teachings of the invention.

What is claimed is:

1. A testing system for testing a charging circuit, comprising:
a setting unit, for setting a charging configuration of the charging circuit according to a battery status message, and allowing the charging circuit to output a charging power according to the charging configuration, when the charging circuit receives an external power supply;
a virtual battery, comprising:
a battery status generating unit, for generating the battery status message to the setting unit according to a first control signal, in order to set the charging configuration of the charging circuit by the setting unit; and
a load unit, for generating a load for the charging circuit according to a second control signal, for receiving the charging power outputted from the charging circuit and recording variation of the charging power; and
a control device, for generating the first control signal and the second control signal, and storing the variation of the charging power, recorded by the load unit, as digital data for evaluating the charging circuit.

2. The testing system of claim 1, wherein the setting unit is a firmware embedded in a portable electronic device.

3. The testing system of claim 1, wherein the setting unit is a virtual firmware controlled by the control device, for setting the charging configuration of the charging circuit according to commands of the control device.

4. The testing system of claim 1, wherein the control device generates the second control signal according to load variation of a rechargeable battery when the rechargeable battery is charged from empty to full power, so as to correlate variation of the load generated by the load unit to the load variation of the rechargeable battery when the rechargeable battery is charged from empty to full power.

5. The testing system of claim 4, wherein the rechargeable battery is charged from empty to full power by a first duration, the load generated by the load unit according to the second control signal shows the load variation of the rechargeable battery when the rechargeable battery is charged from empty to full power by a second duration, and the second duration is shorter than the first duration.

6. The testing system of claim 1, wherein the control device is a computer system.

7. The testing system of claim 1, wherein the charging circuit is embedded in a portable electronic device.

8. A testing method for testing a charging circuit, comprising:
generating a battery status message when the charging circuit receives an external power supply;
setting a charging configuration of the charging circuit according to the battery status message, to control the charging circuit to output a charging power; and
generating a load for the charging circuit, for receiving the charging power outputted from the charging circuit, and recording variation of the charging power, for evaluating the charging circuit.

9. The testing method of claim 8, wherein the step of generating the load for the charging circuit is generating the load according to load variation of a rechargeable battery when the rechargeable battery is charged from empty to full power, so as to correlate variation of the generated load to the load variation of the rechargeable battery when the rechargeable battery is charged from empty to full power.

10. The testing method of claim 9, wherein the rechargeable battery is charged from empty to full power by a first duration, the generated load shows the load variation of the rechargeable battery when the rechargeable battery is charged from empty to full power by a second duration, and the second duration is shorter than the first duration.

11. The testing method of claim 8, wherein the charging circuit is embedded in a portable electronic device.
